(19) United States
(12) Patent Application Publication
(10) Pub. No.: US 2025/0167012 A1
(43) Pub. Date: May 22, 2025

(54) SUBSTRATE PROCESSING APPARATUS AND SUBSTRATE PROCESSING METHOD USING THE SAME

(71) Applicant: SAMSUNG ELECTRONICS CO., LTD., Suwon-si (KR)

(72) Inventors: Jihoon JEONG, Suwon-si (KR); Junho YOON, Suwon-si (KR); Young-Hoo KIM, Suwon-si (KR); Taeheon KIM, Suwon-si (KR); Woogwan SHIM, Suwon-si (KR); Jongwon LEE, Suwon-si (KR); Junho LEE, Suwon-si (KR); Jiwoong JUNG, Suwon-si (KR)

(73) Assignee: SAMSUNG ELECTRONICS CO., LTD., Suwon-si (KR)

(21) Appl. No.: 18/794,556

(22) Filed: Aug. 5, 2024

(30) Foreign Application Priority Data
Nov. 20, 2023 (KR) 10-2023-0160848

(51) Int. Cl. H01L 21/67; B08B 3/04; B08B 3/08; H01L 21/02

(52) U.S. Cl. CPC H01L 21/67051; B08B 3/041; B08B 3/08; H01L 21/02057

(57) ABSTRACT

A substrate processing apparatus includes a stage configured to support a substrate, a rotation driving portion configured to rotate the stage around a first axis extending in a vertical direction, a first nozzle arm disposed on the stage and configured to rotate around a second axis parallel to the first axis, and a second nozzle arm disposed on the stage and configured to rotate around a third axis parallel to the second axis. The first nozzle arm includes a first nozzle supporting member extended parallel to the stage, a first connection member coupled to an end of the first nozzle supporting member, the first connection member having a stepwise shape, and a first nozzle coupled to the first connection member and configured to spray a fluidic material.

### CROSS-REFERENCE TO RELATED APPLICATIONS

This application claims benefit of priority under 35 U.S.C. § 119 to Korean Patent Application No. 10-2023-0160848, filed on Nov. 20, 2023, in the Korean Intellectual Property Office, the disclosure of which is incorporated by reference herein in its entirety.

### BACKGROUND

### 1. Field

The present disclosure relates generally to a substrate processing apparatus and a method of processing a substrate using the same, and more particularly, to a substrate processing apparatus that includes two nozzle arms engaged with each other and allows for a pre-wetting process using organic solvent, and a method of processing a substrate using the same.

### 2. Description of Related Art

A semiconductor device may be fabricated through several processes. When a substrate with the semiconductor device is in an idle stage after a deposition and/or etching process, the substrate may be exposed to the air. In such a case, an oxide layer may be formed on the exposed surface of the substrate. To remove the oxide layer, a step of supplying de-ionized water onto the substrate may be performed in advance, and the oxide layer may be removed from the substrate using a chemical solution. After the removal of the oxide layer, the substrate may be dried using a rotating method and/or using a supercritical fluid.

### SUMMARY

One or more example embodiments of the present disclosure provide a substrate processing apparatus including nozzle arms, which may be engaged with each other, and one of which has a stepwise shape, and a method of processing a substrate using the same.

Further, one or more example embodiments of the present disclosure provide a substrate processing apparatus configured to spray deionized (DI) water and organic solvent onto a center region of a substrate without an excessive delay when compared to a related substrate processing apparatus, and a method of processing a substrate using the same.

Further, one or more example embodiments of the present disclosure provide a substrate processing apparatus used to remove an oxide layer using organic solvent before spraying DI water, and a method of processing a substrate using the same.

Further, one or more example embodiments of the present disclosure provide a substrate processing apparatus configured to spray organic solvent in advance for effective reaction between chemical solution and an oxide layer, and a method of processing a substrate using the same.

According to an aspect of the present disclosure, a substrate processing apparatus includes a stage configured to support a substrate, a rotation driving portion configured to rotate the stage around a first axis extending in a vertical direction, a first nozzle arm disposed on the stage and configured to rotate around a second axis parallel to the first axis, and a second nozzle arm disposed on the stage and configured to rotate around a third axis parallel to the second axis. The first nozzle arm includes a first nozzle supporting member extended parallel to the stage, a first connection member coupled to an end of the first nozzle supporting member, the first connection member having a stepwise shape, and a first nozzle coupled to the first connection member and configured to spray a fluidic material.

According to an aspect of the present disclosure, a substrate processing apparatus includes a stage configured to support a substrate, a rotation driving portion configured to rotate the stage around a first axis, a first nozzle arm disposed on the stage and configured to rotate around a second axis parallel to the first axis, and a second nozzle arm disposed on the first nozzle arm and configured to rotate around the second axis. The first nozzle arm includes a first nozzle supporting member extended parallel to the stage, a first connection member coupled to an end of the first nozzle supporting member, the first connection member having a stepwise shape, and a first nozzle coupled to the first connection member and extended in a vertical direction.

According to an aspect of the present disclosure, a substrate processing method includes placing a substrate in a substrate processing apparatus, and processing the substrate. The processing of the substrate includes spraying, from a first nozzle, organic solvent onto a stage of the substrate processing apparatus, spraying, from a second nozzle, DI water toward a center region of the stage, and spraying, from a third nozzle, a chemical solution. The first nozzle is coupled to a first connection member, the first connection member being coupled to an end of a first nozzle supporting member, the first connection member having a stepwise shape, the first nozzle supporting member being extended toward the center region of the stage and parallel to the stage, a first nozzle arm of the substrate processing apparatus including the first nozzle supporting member, the first connection member, and the first nozzle, the first nozzle arm being disposed on the stage to rotate around a second axis perpendicular to the top surface of the stage. The second nozzle arm of the substrate processing apparatus includes the second nozzle and the third nozzle, the second nozzle arm being disposed on the stage to rotate around a third axis parallel to the second axis. The substrate processing apparatus includes a rotation driving portion rotating the stage around a first axis perpendicular to a top surface of the stage.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a perspective view illustrating a substrate processing apparatus, according to an embodiment;

FIG. 2 is a front view illustrating a substrate processing apparatus, according to an embodiment;

FIG. 3 is a top view illustrating a substrate processing apparatus, according to an embodiment;

FIG. 4 is a top view illustrating a substrate processing apparatus, according to an embodiment;

FIG. 5 is a perspective view illustrating a connection member, according to an embodiment;

FIG. 6 is a perspective view illustrating a substrate processing apparatus, according to an embodiment;

FIG. 7 is a front view illustrating a substrate processing apparatus, according to an embodiment;

FIG. 8 is a top view illustrating a substrate processing apparatus, according to an embodiment;

FIG. 9 is a perspective view illustrating a connection member, according to an embodiment;

FIG. 10 is a side view illustrating a connection member, according to an embodiment;

FIG. 11 is a flow chart illustrating a substrate processing method, according to an embodiment;

FIG. 12 is a front view illustrating a substrate before a cleaning operation in the substrate processing method, according to an embodiment;

FIG. 13 is a front view illustrating a substrate after a deionized (DI) water spraying operation in the substrate processing method, according to an embodiment;

FIG. 14 is a front view illustrating a substrate after the cleaning operation in the substrate processing method, according to an embodiment;

FIG. 15 is a front view illustrating a substrate after a DI water spraying operation in the substrate processing method, according to an embodiment; and

FIG. 16 is a front view illustrating a substrate after the cleaning operation in the substrate processing method, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

As used herein, each of the terms “AlN”, “HF”, and the like may refer to a material made of elements included in each of the terms and is not a chemical formula representing a stoichiometric relationship.

As used herein, the reference numbers D1, D2, and D3 may be used to denote a first direction, a second direction, and a third direction, respectively, which may not be parallel to each other.

Hereinafter, various embodiments of the present disclosure are described with reference to the accompanying drawings.

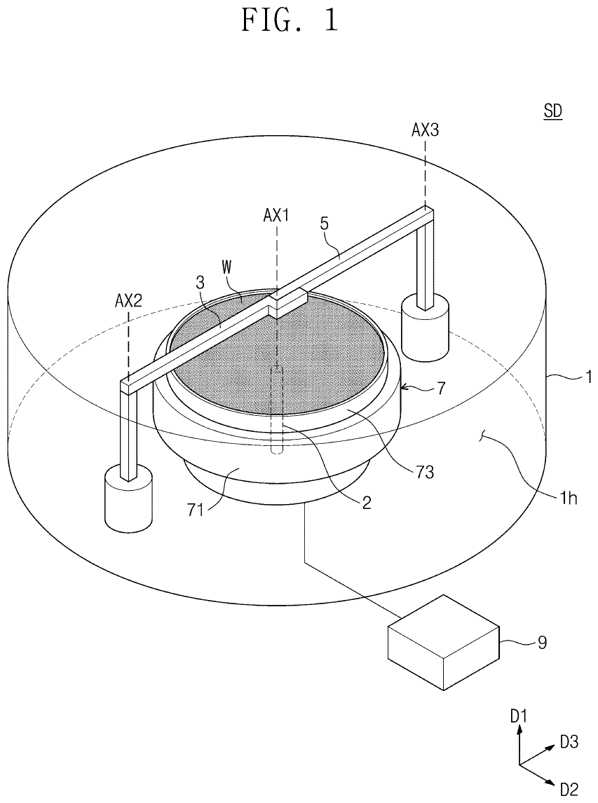

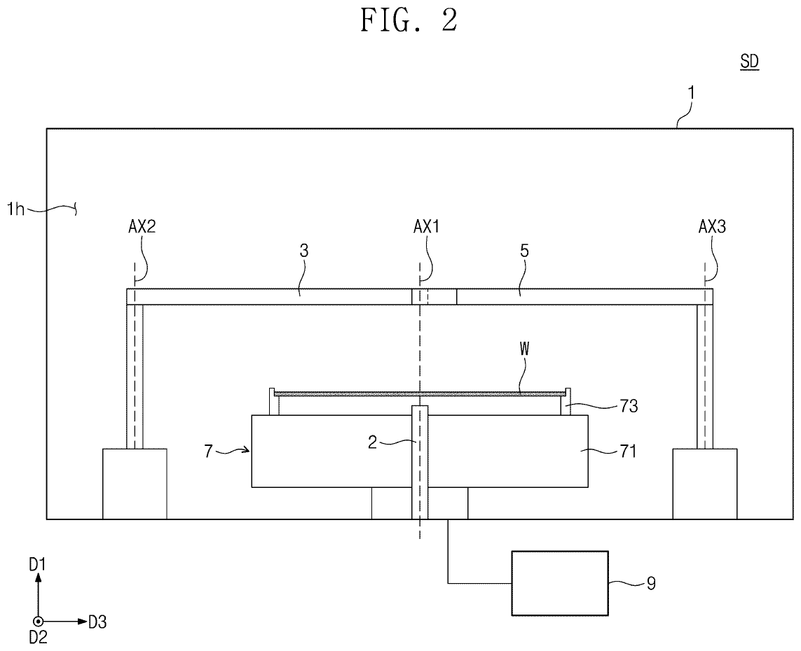

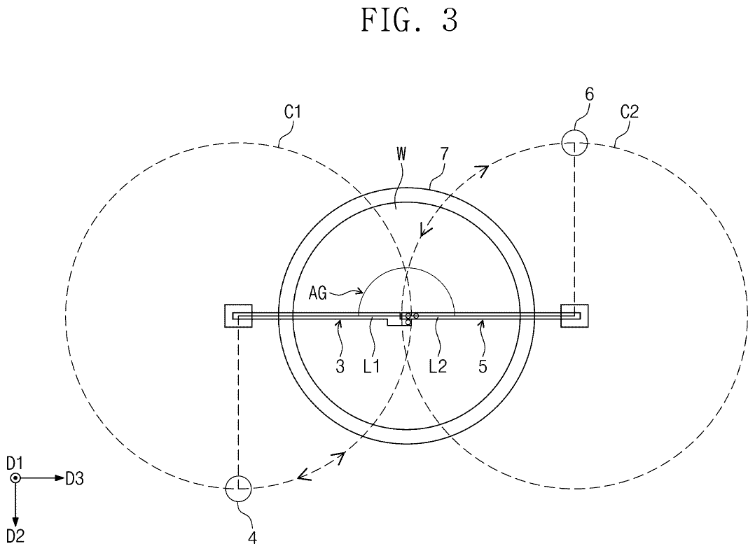

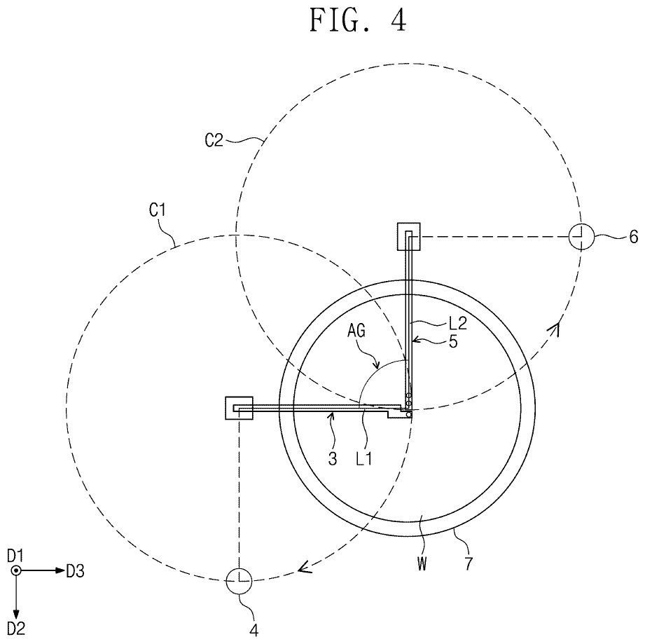

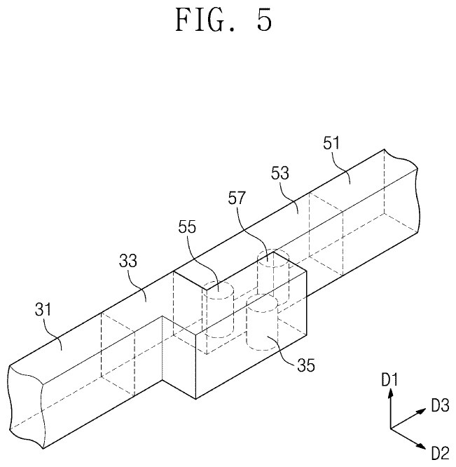

FIG. 1 is a perspective view illustrating a substrate processing apparatus SD, according to an embodiment. FIG. 2 is a front view illustrating the substrate processing apparatus SD, according to an embodiment. FIG. 3 is a top view illustrating the substrate processing apparatus SD, according to an embodiment. FIG. 4 is a top view illustrating the substrate processing apparatus SD, according to an embodiment. FIG. 5 is a perspective view illustrating connection members, according to an embodiment.

Referring to FIGS. 1 and 2, the substrate processing apparatus SD may be provided. The substrate processing apparatus SD may include a process chamber 1, a first nozzle arm 3, a second nozzle arm 5, a third nozzle arm 2, a stage 7, and a rotation driving portion 9.

The process chamber 1 may include a process space 1h. A process on a substrate W may be performed in the process space 1h. The process space 1h may be isolated from an external space. The process chamber 1 may be separated to allow the substrate W to move from the external space into the process space 1h. The process chamber 1 may include a substrate insertion hole, which may be used to load the substrate W from the external space to the process space 1h. The process chamber 1 may have a shape of a circular cylinder. However, the present disclosure is not limited to this example, and the process chamber 1 may have various other shapes.

The stage 7 may be placed in the process chamber 1. For example, the stage 7 may be placed in the process space 1h. The stage 7 may be used to support and/or fasten the substrate W. The process on the substrate W may be performed after the substrate W is loaded on the stage 7. The stage 7 may include a stage body 71 and a substrate supporting fixture 73. The stage body 71 may include, but not be limited to, aluminum nitride (AlN), aluminum (Al), or the like. However, the present disclosure is not limited in this regard.

The stage body 71 may further include a material with heat resistance and/or chemical resistance. The stage body 71 may have a shape of a circular plate. However, the present disclosure is not limited to this example, and the stage body 71 may have various other shapes. A diameter of the stage body 71 may be larger than the substrate W. For example, the diameter of the stage body 71 may be larger than or equal to 300 millimeters (mm). The substrate supporting fixture 73 may be used to place the substrate W at a level that may be spaced apart from a top surface of the stage body 71. The stage 7 may be rotated by the rotation driving portion 9. That is, the stage 7 may rotate around a first axis AX1 in a clockwise and/or counterclockwise direction by the rotation driving portion 9. The first axis AX1 may pass through a center region of the stage 7 and may be extended in a direction perpendicular to the top surface of the stage body 71.

The first nozzle arm 3 may be configured to spray a fluidic material toward the stage 7. The first nozzle arm 3 may be placed in the process chamber 1. For example, the first nozzle arm 3 may be placed in the process space 1h. The first nozzle arm 3 may be located over the stage 7. The first nozzle arm 3 may rotate around a second axis AX2 parallel to the first axis AX1. The first nozzle arm 3 may include a first nozzle supporting member 31, a first connection member 33, and a first nozzle 35. The first nozzle supporting member 31 may be extended to be parallel to the stage 7. The first nozzle supporting member 31 may be extended toward the center region of the stage 7. The first connection member 33 may be connected to an end of the first nozzle supporting member 31.

Referring to FIG. 5, the first connection member 33 may have a stepwise shape. That is, the first connection member 33 may have a stepwise shape and may be extended toward the center region of the stage 7 in a horizontal direction. The first connection member 33 may have a stepwise shape, which may include portions that may be bent in the second direction D2 and the third direction D3, respectively, perpendicular to the first direction D1. However, the shape of the first connection member 33 is not limited to this example.

The first nozzle 35 may be configured to spray the fluidic material. The first nozzle 35 may spray the fluidic material toward the center region of the stage 7. The first nozzle 35 may be connected to the first connection member 33. The first nozzle 35 may be coupled to the first connection member 33. The first nozzle 35 may be extended in a vertical direction, and as such, the fluidic material may be sprayed toward the center region of the stage 7.

The fluidic material, which may be sprayed from the first nozzle 35, may include, but not be limited to, deionized (DI) water, an organic solvent, a chemical solution, or the like. The organic solvent may include, but not be limited to, ether, acetate, alcohol, isopropyl alcohol (IPA), or the like. However, the organic solvent is not limited in this regard. For example, the organic solvent may further include another material, which may be mixed with hydrophilic and/or hydrophobic substances. The organic solvent may further include another material that may enable effective mixing of the hydrophilic and the hydrophobic substances. In an embodiment, the surface tension of the organic solvent may be less than or equal to 72 dyne/cm at room temperature.

The chemical solution may be used to remove an oxide layer. The chemical solution may be and/or may include hydrofluoric acid. For example, the hydrofluoric acid may be and/or may include a solution of hydrogen fluoride (HF). However, the present disclosure is not limited in this regard, and the chemical solution may be a compound containing hydrofluoric acid. Alternatively or additionally, the chemical solution may contain a compound of hydrogen fluoride (HF). In an embodiment, the chemical solution may contain a plurality of various types of substances.

The second nozzle arm 5 may be configured to spray a fluidic material toward the stage 7. The second nozzle arm 5 may be placed in the process chamber 1. For example, the second nozzle arm 5 may be placed in the process space 1h. The second nozzle arm 5 may be placed over the stage 7. The second nozzle arm 5 may rotate around a third axis AX3 parallel to the second axis AX2. Referring to FIG. 3, a straight line connecting (e.g., extending from) the second axis AX2 to the third axis AX3 may pass through a center region of the substrate W and a center region of the stage body 71. The straight line connecting the second axis AX2 to the third axis AX3 may pass through the first axis AX1. However, a relative position between the second and third axes AX2 and AX3 is not limited to this example. That is, the disposition of the first and second nozzle arms 3 and 5 is not limited to this example.

Referring to FIGS. 3 and 4, a straight line connecting the first axis AX1 to the second axis AX2 in a horizontal direction may be referred to as a first straight line L1. A straight line connecting the first axis AX1 to the third axis AX3 in a horizontal direction may be referred to as a second straight line L2. An angle AG between the first and second straight lines L1 and L2 may be changed. For example, the angle AG between the first and second straight lines L1 and L2 may range from 10 degrees (°) to 180°. For example, referring to FIG. 3, the angle AG between the first and second straight lines L1 and L2 may be 180°. As another example, an angle between the first and second nozzle arms 3 and 5 may be 180°. When the angle AG between the first and second straight lines L1 and L2 is reduced, a relative position of the second axis AX2 with respect to the first axis AX1 may be changed. Referring to FIG. 4, the angle AG between the first and second straight lines L1 and L2 may be 90°. That is, an angle between the first and second nozzle arms 3 and 5 may be 90°. However, the angle AG between the first and second straight lines L1 and L2 may not be limited to the examples shown in FIGS. 3 and 4. That is, an angle between the first and second nozzle arms 3 and 5 may not be limited to the examples shown in FIGS. 3 and 4.

An imaginary circle, which has the first nozzle arm 3 as a radius, may be referred to as a first circle C1. In an embodiment, the first circle C1 may refer to a range of rotation of the first nozzle arm 3. An imaginary circle, which has the second nozzle arm 5 as a radius, may be referred to as a second circle C2. In an embodiment, the first circle C1 may refer to a range of rotation of the second nozzle arm 5. The first and second circles C1 and C2 may be in contact with each other and/or may be overlapped with each other. That is, the first and second circles C1 and C2 may meet each other at a single point or at two points. A sum of lengths of the first and second nozzle arms 3 and 5 may be larger than a diameter of the stage 7. A level of the first nozzle arm 3 may be equal to a level of the second nozzle arm 5. However, the present disclosure is not limited to this example, and the level of the first nozzle arm 3 may be different from the level of the second nozzle arm 5.

The second nozzle arm 5 may include a second nozzle supporting member 51, a second connection member 53, and a second nozzle 55. The second nozzle supporting member 51 may be perpendicular to the third axis AX3. The second nozzle supporting member 51 may be placed on the stage. The second nozzle supporting member 51 may be extended straight toward the center region of the stage 7. The second connection member 53 may be connected to an end of the second nozzle supporting member 51. The second connection member 53 may have a rectangular parallelepiped shape. However, the present disclosure is not limited in this regard. For example, the second connection member 53 may have a stepwise shape. In such an example, the second connection member 53 may have a shape that may be substantially similar and/or the same as the first connection member 33. The second connection member 53 may have various shapes that may engage with the first connection member 33.

When the second connection member 53 is engaged with the first connection member 33, a horizontal distance between the first and second nozzles 35 and 55 may be reduced. As the horizontal distance between the first and second nozzles 35 and 55 is reduced, the fluidic material may be sprayed onto the substrate W on the stage 7 with a reduced time interval. The second nozzle 55 may spray the fluidic material toward the center region of the stage 7 in a vertical direction. The fluidic material, which may be sprayed from the second nozzle 55, may include, but not be limited to, DI water, an organic solvent, a chemical solution, or the like.

The second nozzle arm 5 may further include a third nozzle 57. The fluidic material, which may be sprayed from the third nozzle 57, may include, but not be limited to, DI water, an organic solvent, a chemical solution, or the like. The fluidic materials, which may be respectively sprayed from the first nozzle 35, the second nozzle 55, and the third nozzle 57, may be of different types. To spray a single type of fluidic material, only one nozzle may be used. In an embodiment, the first nozzle 35 may be used to spray the organic solvent. In such an embodiment, the second nozzle 55 may be used to spray the deionized water. Alternatively or additionally, the third nozzle 57 may be used to spray the chemical solution.

The third nozzle arm 2 may be configured to spray a fluidic material. That is, the third nozzle arm 2 may be configured to spray the fluidic material onto a rear surface of the substrate W. The third nozzle arm 2 may be extended in a vertical direction. The third nozzle arm 2 may penetrate the stage body 71 in the vertical (e.g., upward or downward) direction. A level of a top surface of the third nozzle arm 2 may be lower than a level of a top surface of the substrate supporting fixture 73. The fluidic material, which may be sprayed from the third nozzle arm 2, may include DI water. However, the present disclosure is not limited in this regard.

Referring to FIGS. 3 and 4, the substrate processing apparatus SD may further include a first home port 4 and a second home port 6. The first home port 4 may be a place where the first nozzle arm 3 is positioned in a standby stage. After the standby stage, the first nozzle arm 3 may be rotated from the first home port 4 to a region over the stage 7. The second home port 6 may be a place where the second nozzle arm 5 is positioned in a standby stage. After the standby stage, the second nozzle arm 5 may be rotated from the second home port 6 to a region over the stage 7.

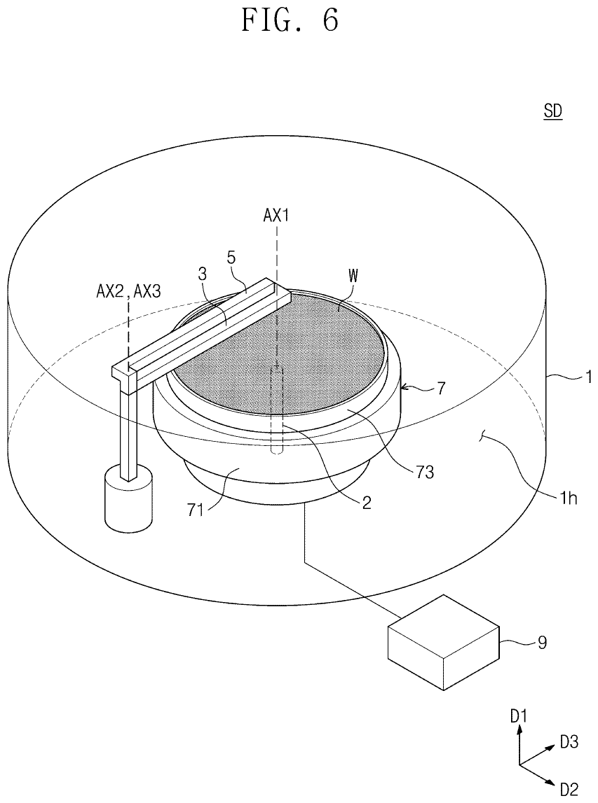

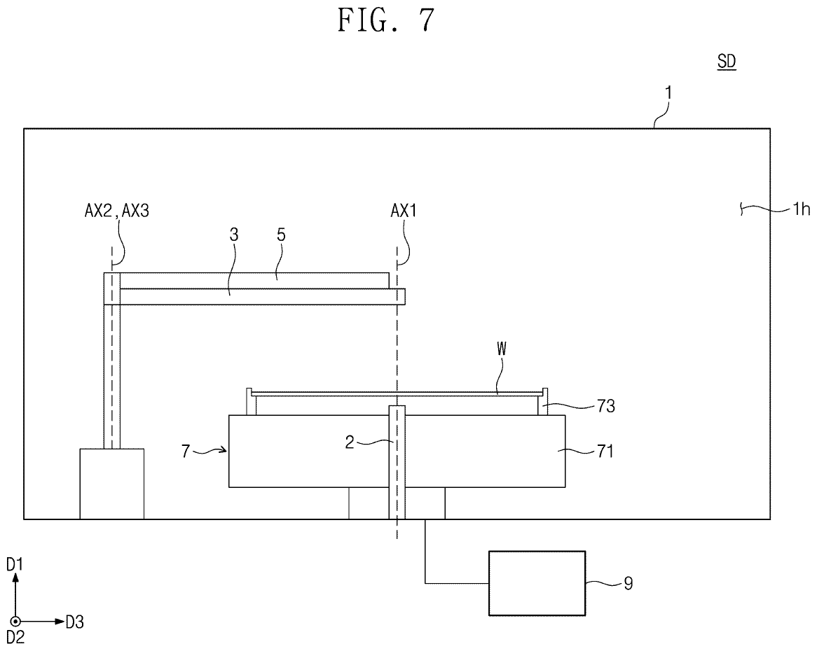

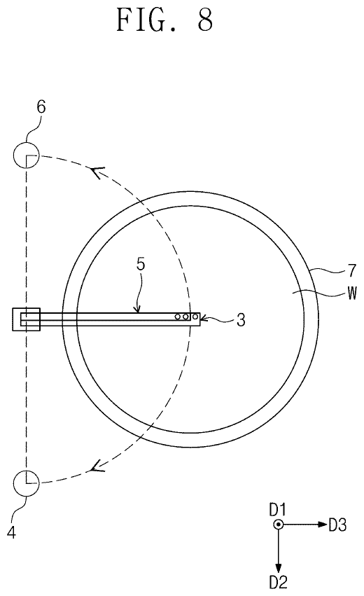

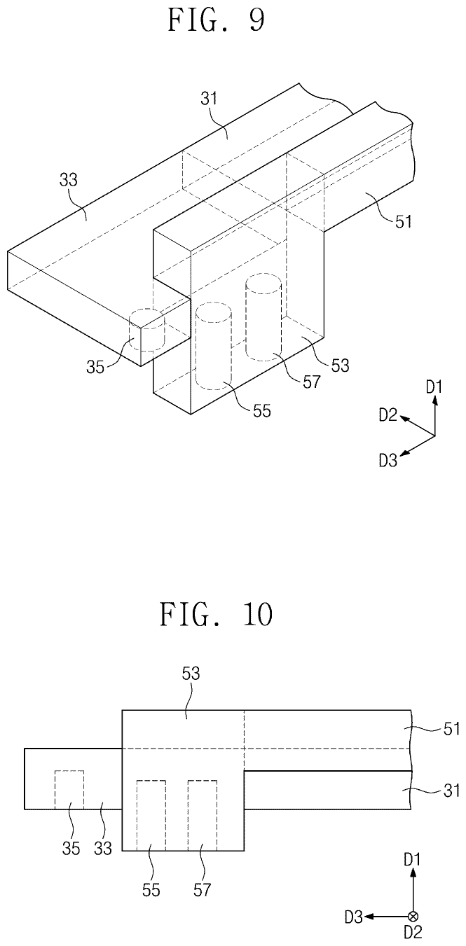

FIG. 6 is a perspective view illustrating the substrate processing apparatus SD, according to an embodiment. FIG. 7 is a front view illustrating a substrate processing apparatus, according to an embodiment. FIG. 8 is a top view illustrating the substrate processing apparatus SD, according to an embodiment. FIG. 9 is a perspective view illustrating connection members 33 and 53, according to an embodiment. FIG. 10 is a side view illustrating connection members, according to an embodiment.

Referring to FIGS. 6 and 7, the second axis AX2 may be the same as the third axis AX3. The second nozzle supporting member 51 may be placed on the first nozzle supporting member 31. A level of a top surface of the second nozzle supporting member 51 may be higher than a level of a top surface of the first nozzle supporting member 31. The first axis AX1 may penetrate the second nozzle supporting member 51 and the first nozzle supporting member 31. Referring to FIGS. 7 and 8, the first and second nozzle arms 3 and 5 may be rotated in opposite directions to each other. However, the present disclosure is not limited in this regard. For example, the first and second nozzle arms 3 and 5 may be engaged with each other.

Referring to FIGS. 9 and 10, the second connection member 53 may be extended in a vertical direction. The second nozzle 55 may be extended in the vertical direction. A level of a bottom surface of the second connection member 53 may be lower than the level of the top surface of the first nozzle supporting member 31. A level of a bottom surface of the second nozzle 55 may be lower than the level of the top surface of the first nozzle supporting member 31. However, the present disclosure is not limited to this example, and the level of the bottom surface of the second nozzle 55 may be lower than a level of a bottom surface of the first nozzle supporting member 31.

In an embodiment, the first and second nozzle arms 3 and 5 may be rotated in the same direction. In an embodiment, the second nozzle arm 5 may physically impede the rotation of the first nozzle arm 3. For example, the second connection member 53 may hinder the rotation of the first nozzle arm 3 toward the second nozzle supporting member 51.

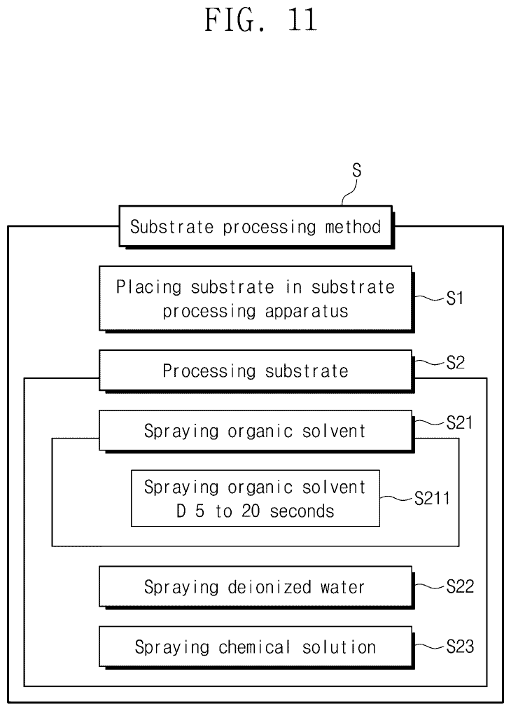

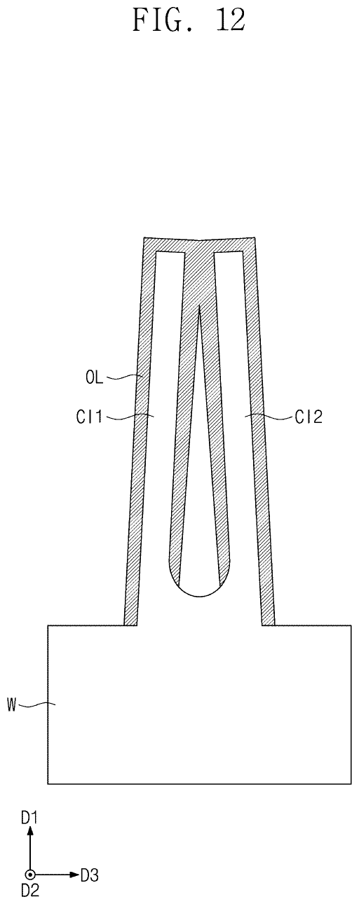

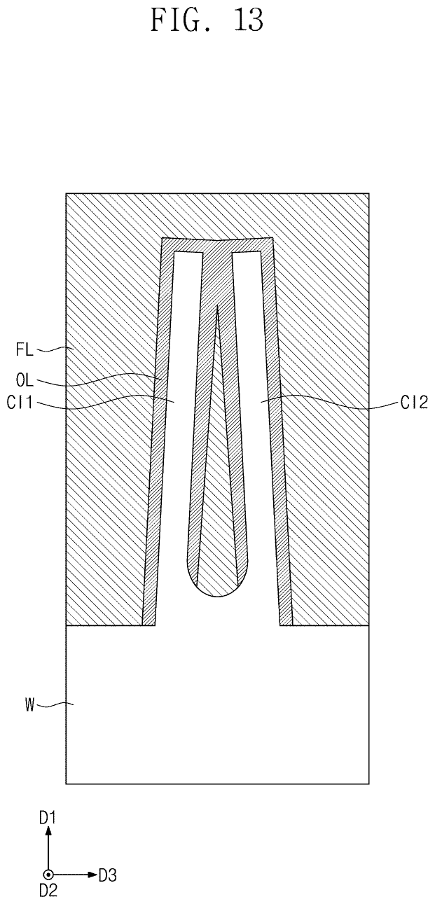

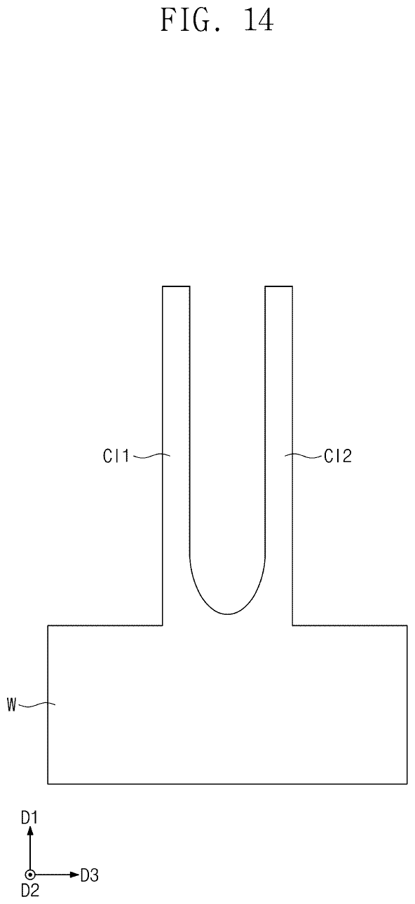

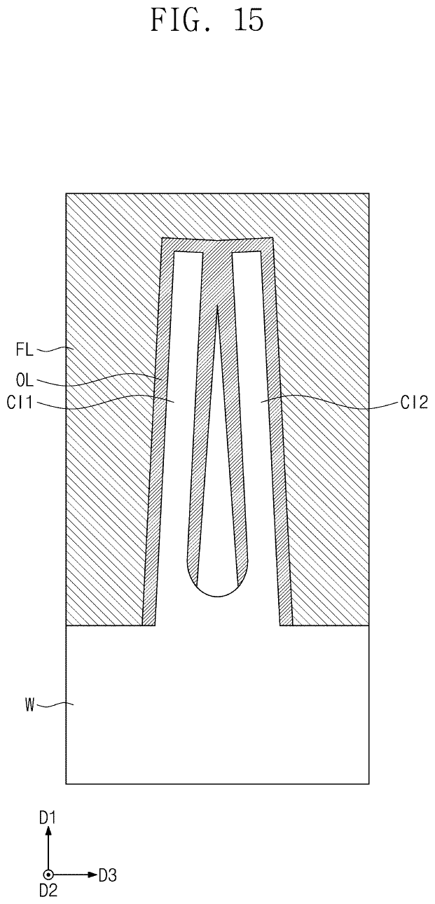

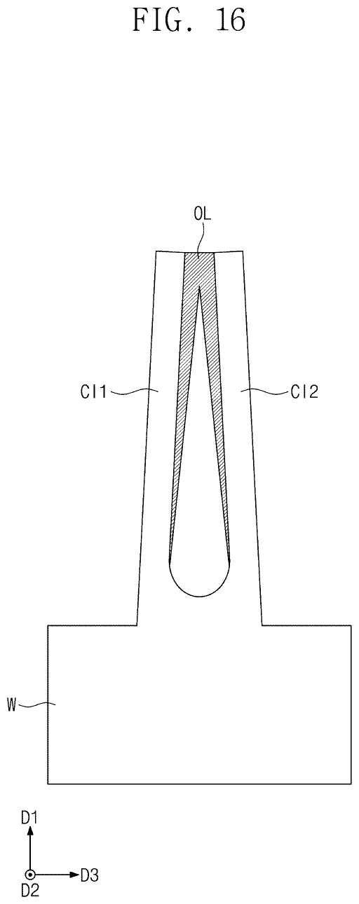

FIG. 11 is a flow chart illustrating a substrate processing method S, according to an embodiment. FIG. 12 is a front view illustrating the substrate W before a cleaning operation in the substrate processing method S, according to an embodiment. FIG. 13 is a front view illustrating the substrate W after a DI water spraying operation in the substrate processing method S, according to an embodiment. FIG. 14 is a front view illustrating the substrate W after the cleaning operation in the substrate processing method S, according to an embodiment. FIG. 15 is a front view illustrating the substrate W after the DI water spraying operation in the substrate processing method S, according to an embodiment. FIG. 16 is a front view illustrating the substrate W after the cleaning operation in the substrate processing method S, according to an embodiment.

Referring to FIG. 11, the substrate processing method S may include placing the substrate W in the substrate processing apparatus SD (in operation S1) and processing the substrate W (in operation S2). The processing of the substrate W (in operation S2) may include spraying an organic solvent (in operation S21), spraying DI water (in operation S22), and spraying a chemical solution (in operation S23). The spraying of the organic solvent (in operation 21) may include spraying the organic solvent for a time duration between 5 seconds and 20 seconds (in operation S211).

Referring to FIG. 12, the substrate W with an oxide layer OL may be provided. The substrate W may include a first column C11 and a second column C12. The first and second columns C11 and C12 may be portions of the substrate W, which may be left after etching the substrate W. However, the present disclosure is not limited in this regard. Top surfaces of the first and second columns C11 and C12 may be located at a level that may be higher than the etched portions of the substrate W.

When the substrate W is exposed to the air, a surface of the substrate W may be oxidized. For example, when the substrate W is exposed to the air, the oxide layer OL may be formed on the surface of the substrate W. The first and second columns C11 and C12 may be connected to each other by the oxide layer OL. In an embodiment, the first and second columns C11 and C12 may be inclined toward each other by the oxide layer OL.

Referring to FIG. 13, the substrate W, on which the organic solvent, the DI water, and the chemical solution are sprayed (in operations S21, S22, and S23) is illustrated. As shown in FIG. 13, a mixed fluidic material FL on the oxide layer OL may be and/or may include a mixture of the organic solvent, the DI water, and the chemical solution. However, the present disclosure is not limited in this regard, and the mixed fluidic material FL may further include an additional material.

In an embodiment, the oxide layer OL may exhibit hydrophobicity. For example, the oxide layer OL may not be in contact with the DI water with ease. In an embodiment, the organic solvent may facilitate a mixing of hydrophilic substances and hydrophobic substances. That is, the organic solvent may be effectively mixed with both the hydrophilic and hydrophobic substances. In such an embodiment, the organic solvent may cause the oxide layer OL to react with the DI water.

The chemical solution may be mixed in a region with the DI water. The oxide layer OL may be removed by the chemical solution. FIG. 14 illustrates the substrate W, from which the oxide layer OL has been removed by the chemical solution. The chemical solution may be supplied into the region between the first and second columns C11 and C12 to remove the oxide layer OL. The first and second columns C11 and C12, from which the oxide layer OL is removed, may be extended in a vertical direction, as shown in FIG. 14.

FIG. 15 illustrates the substrate W, on which the DI water and the chemical solution are sprayed (in operations S22 and S23) but on which the organic solvent may not have been sprayed. As shown in FIG. 15, the mixed fluidic material FL may be and/or may include a mixture of the DI water and the chemical solution. In an embodiment, an additional material may be further included in the mixed fluidic material FL. The DI water may not be supplied into a region between the first and second columns C11 and C12. The chemical solution may not be supplied the region between the first and second columns C11 and C12, in which the DI water may not have been supplied.

FIG. 16 illustrates the substrate W, from which a portion of the oxide layer OL is not removed. The oxide layer OL may not be removed from a region, in which the chemical solution may not have been supplied. In such an example, the first and second columns C11 and C12 may be connected to each other by the oxide layer OL. Alternatively or additionally, the first and second columns C11 and C12 may be inclined toward each other by the oxide layer OL, as shown in FIG. 16.

After the spraying of the chemical solution toward the substrate W, the DI water may be sprayed onto the substrate W. The DI water, which may be sprayed onto the substrate W, may be used to remove the chemical solution from the substrate W. After the cleaning of the substrate W using the DI water, the organic solvent may be sprayed onto the substrate W, and as a result, a surface tension of liquid on the substrate W may be reduced (e.g., lowered). Thereafter, the substrate W may be dried by a rotating method and/or using a supercritical fluid.

In a substrate processing apparatus, according to an embodiment, and a method of processing a substrate using the same, it may be possible to spray various solutions onto a center region of a stage without an excessive delay, when compared to a related substrate processing apparatus. For example, a first nozzle arm and a second nozzle arm, which may be engaged with each other, may be provided, and after an operation of spraying solution from the first nozzle arm toward the center region of the stage, it may be possible to spray solution from the second nozzle arm toward the center region of the stage immediately (e.g., without additional motion). Alternatively or additionally, after the operation of spraying solution from the first nozzle arm toward the center region of the stage, the second nozzle arm may be placed on a desired position in the center region of the stage within a reduced time interval, and as a result, may potentially reduce a time interval between the operations of spraying the solutions from the first and second nozzle arms. Since the time interval between the solution spraying operations is reduced, the surface of the substrate may potentially be prevented from being dried.

In a substrate processing apparatus, according to an embodiment, and a method of processing a substrate using the same, it may be possible to remove an oxide layer from a surface of the substrate and thereby to potentially prevent patterns of the substrate from being collapsed. When the substrate is exposed to the air, an oxide layer may be formed on the surface of the substrate. If such an oxide layer is not removed, different portions of the oxide layer may be in contact with each other, which may lead to a failure of a semiconductor chip (e.g., deformation and/or collapse of the substrate patterns). The oxide layer may be removed using a chemical solution. For example, an organic solvent may be first sprayed onto the surface of the substrate. The chemical solution may be supplied into a deep region of the substrate to remove the oxide layer from the deep region. The organic solvent may have small polarity dependence, which may enable the organic solvent to mix and/or combine with hydrophilic and/or hydrophobic substances. When the organic solvent and the DI water are sequentially sprayed onto the substrate, the DI water, which may be a hydrophilic solution, may be combined with the oxide layer, which may be a hydrophobic material, and thus, the chemical solution may be effectively supplied throughout the substrate.

In a substrate processing apparatus, according to an embodiment, and a method of processing a substrate using the same, nozzle arms may be provided. In an embodiment, one of the nozzle arms may have a stepwise shape, which may allow the nozzle arms to engage with each other.

In a substrate processing apparatus, according to an embodiment, and a method of processing a substrate using the same, the substrate processing apparatus may spray DI water and organic solvent onto a center region of a substrate without an excessive delay when compared to a related substrate processing apparatus.

In a substrate processing apparatus, according to an embodiment, and a method of processing a substrate using the same, an organic solvent, which may be sprayed before DI water, may be used to effectively remove an oxide layer from a substrate.

In a substrate processing apparatus, according to an embodiment, and a method of processing a substrate using the same, an organic solvent may be used in advance of spraying a chemical solution to facilitate an effective reaction between the chemical solution and an oxide layer.

While example embodiments of the present disclosure have been particularly shown and described, it may be understood by one of ordinary skill in the art that variations in form and detail may be made therein without departing from the spirit and scope of the attached claims.

What is claimed is:

1. A substrate processing apparatus, comprising:
a stage configured to support a substrate;
a rotation driving portion configured to rotate the stage around a first axis extending in a vertical direction;
a first nozzle arm disposed on the stage and configured to rotate around a second axis parallel to the first axis; and
a second nozzle arm disposed on the stage and configured to rotate around a third axis parallel to the second axis,
wherein the first nozzle arm comprises:
a first nozzle supporting member extended parallel to the stage;
a first connection member coupled to an end of the first nozzle supporting member, the first connection member having a stepwise shape; and
a first nozzle coupled to the first connection member and configured to spray a fluidic material.

2. The apparatus of claim 1, wherein an angle between a first straight line and a second straight line ranges from 10 degrees to 180 degrees,
wherein the first straight line extends from the first axis to the second axis in a horizontal direction, and
wherein the second straight line extends from the first axis to the third axis in a horizontal direction.

3. The apparatus of claim 1, wherein the second axis is same as the third axis,
wherein the second nozzle arm comprises:
a second nozzle supporting member disposed perpendicular to the third axis;
a second connection member coupled to an end of the second nozzle supporting member; and
a second nozzle coupled to the second connection member, and
wherein the second nozzle supporting member is disposed on the first nozzle supporting member.

4. The apparatus of claim 3, wherein the second connection member is extended in a vertical direction,
wherein a level of a top surface of the second nozzle supporting member is higher than a level of a top surface of the first nozzle supporting member, and
wherein a level of a bottom surface of the second connection member is lower than the level of the top surface of the first nozzle supporting member.

5. The apparatus of claim 2, wherein the second nozzle arm comprises:
a second nozzle supporting member disposed perpendicular to the third axis;
a second connection member coupled to an end of the second nozzle supporting member; and
a second nozzle coupled to the second connection member and configured to spray another fluidic material,
wherein the second connection member comprises a stepwise portion extended from the end of the second nozzle supporting member, and
wherein the first connection member and the second connection member are engaged with each other.

6. The apparatus of claim 2, wherein the first nozzle arm and the second nozzle arm are disposed at a same level, and
wherein a first range of rotation of the first nozzle arm and a second range of rotation of the second nozzle arm meet at a one or two points.

7. The apparatus of claim 1, wherein the stage comprises:
a stage body having a shape of a circular plate; and
a substrate supporting fixture configured to dispose the substrate at a level that is spaced apart from a top surface of the stage body.

8. The apparatus of claim 7, further comprising:
a third nozzle arm extended to at least partially penetrate the stage body in a vertical direction,
wherein a level of a top surface of the third nozzle arm is lower than a level of a top surface of the substrate supporting fixture.

9. A substrate processing apparatus, comprising:
a stage configured to support a substrate;
a rotation driving portion configured to rotate the stage around a first axis;
a first nozzle arm disposed on the stage and configured to rotate around a second axis parallel to the first axis; and
a second nozzle arm disposed on the first nozzle arm and configured to rotate around the second axis,
wherein the first nozzle arm comprises:
a first nozzle supporting member extended parallel to the stage;
a first connection member coupled to an end of the first nozzle supporting member, the first connection member having a stepwise shape; and
a first nozzle coupled to the first connection member and extended in a vertical direction.

10. The apparatus of claim 9, wherein the second nozzle arm comprises:
a second nozzle supporting member extended in a direction perpendicular to the second axis;
a second connection member coupled to an end of the second nozzle supporting member; and
a second nozzle coupled to the second connection member and configured to spray a fluidic material,
wherein the second nozzle and the second connection member are extended in a vertical direction.

11. The apparatus of claim 10, wherein the first nozzle arm and the second nozzle arm are configured to rotate in opposite directions.

12. The apparatus of claim 9, wherein the stage comprises:
a stage body having a shape of a circular plate; and
a substrate supporting fixture configured to dispose the substrate at a level that is spaced apart from a top surface of the stage body.

13. The apparatus of claim 12, further comprising:
a third nozzle arm configured to at least partially penetrate the stage body in a vertical direction and to spray a fluidic material.

14. The apparatus of claim 10, wherein a level of a bottom surface of the second connection member is lower than a level of a top surface of the first nozzle supporting member, and
wherein the second connection member hinders the first nozzle arm from being rotated toward the second nozzle supporting member.

15. A substrate processing method, comprising:
placing a substrate in a substrate processing apparatus; and
processing the substrate,
wherein the processing of the substrate comprises:
spraying, from a first nozzle, organic solvent onto a stage of the substrate processing apparatus;
spraying, from a second nozzle, deionized (DI) water toward a center region of the stage; and
spraying, from a third nozzle, a chemical solution,
wherein the first nozzle is coupled to a first connection member, the first connection member being coupled to an end of a first nozzle supporting member, the first connection member having a stepwise shape, the first nozzle supporting member being extended toward the center region of the stage and parallel to the stage, a first nozzle arm of the substrate processing apparatus comprising the first nozzle supporting member, the first connection member, and the first nozzle, the first nozzle arm being disposed on the stage to rotate around a second axis perpendicular to the top surface of the stage,
wherein a second nozzle arm of the substrate processing apparatus comprises the second nozzle and the third nozzle, the second nozzle arm being disposed on the stage to rotate around a third axis parallel to the second axis, and
wherein the substrate processing apparatus comprises a rotation driving portion rotating the stage around a first axis perpendicular to a top surface of the stage.

16. The substrate processing method of claim 15, wherein the spraying of the organic solvent comprises:
spraying, from the first nozzle, the organic solvent having a surface tension less than or equal to 72 dyne/cm.

17. The substrate processing method of claim 15, wherein the spraying of the organic solvent comprises:
spraying, from the first nozzle, the organic solvent comprising at least one of ether, acetate, alcohol, or isopropyl alcohol (IPA).

18. The substrate processing method of claim 15, wherein the spraying of the organic solvent comprises:
spraying, from the first nozzle, the organic solvent for a time duration in a range of 5 to 20 seconds.

19. The apparatus of claim 1, wherein a sum of a first length of the first nozzle arm and a second length of the second nozzle arm is greater than a diameter of the stage.

20. The apparatus of claim 1, wherein the first axis is same as the second axis, and
wherein the first nozzle arm is disposed at a first level, and
wherein the second nozzle arm is disposed at a second level different from the first level.
